(19) United States
(12) Patent Application Publication
(10) Pub. No.: US 2014/0192606 A1
(43) Pub. Date: Jul. 10, 2014

(54) STACKED MEMORY DEVICE, MEMORY SYSTEM INCLUDING THE SAME AND METHOD FOR OPERATING THE SAME

(71) Applicant: Samsung Electronics Co., Ltd., Suwon-si (KR)

(72) Inventors: Gil Young KANG, Seoul (KR); Chi Sung OH, Suwon-si, Gyeonggi-do (KR)

(73) Assignee: Samsung Electronics Co., Ltd., Suwon-si (KR)

(21) Appl. No.: 14/103,090

(22) Filed: Dec. 11, 2013

(30) Foreign Application Priority Data
Jan. 8, 2013 (KR) 10-2013-0002143

(51) Int. Cl. G11C 7/00

(52) U.S. Cl. CPC G11C 7/00
USPC 365/222

(57) ABSTRACT

A stacked memory device includes a plurality of interconnected memory chips and a controller to control the plurality of memory chips to perform refresh operations during non-overlapping time periods. Each memory chip includes a plurality of ranks, and each rank includes at least one memory bank. In one arrangement, the controller controls the refresh operation to be selectively performed for a first rank in each of the memory chips during the non-overlapping time periods independently from a refresh operation performed for a second rank in each memory chip. Delay circuits or other logic may be included to ensure that the refresh operations do not overlap.

### CROSS-REFERENCE TO RELATED APPLICATION

Korean Patent Application No. 10-2013-0002143, filed on Jan. 8, 2013, and entitled, “Stacked Memory Device, Memory System Including the Same and Method for Operating the Same,” is incorporated by reference herein in its entirety.

### BACKGROUND

1. Field

One or more embodiments described herein a memory device.

2. Description of the Related Art

A stacked memory device has been widely used in electronic devices to store data. A stacked memory device may include a plurality of memory chips, each of which includes a plurality of ranks. When each rank is embodied within a volatile memory such as dynamic random access memory (DRAM), a refresh operation needs to be performed periodically.

Generally, each rank includes a plurality of banks, and each bank may include a plurality of rows or a plurality of word lines, a plurality of bit lines, and a plurality of memory cells for storing data. When performed on such a device, a refresh operation may perform a row access with respect to all the rows. However, a peak current may be generated when the ranks in the memory chips perform the refresh operation at the same time. This peak current may affect the reliability of the stacked memory device.

### SUMMARY

In accordance with one embodiment, a stacked memory device includes a plurality of a plurality of memory chips; a first path to transmit a command signal to at least one of the plurality of memory chips; and a second path coupled to the plurality of memory chips, the second path to transmit a refresh control signal for controlling a refresh operation of at least one of the plurality of memory chips.

Also, the stacked memory device may include a memory controller to control the plurality of memory chips, wherein the memory controller includes a generator to generate the refresh control signal. At least one of the plurality of memory chips includes a refresh control circuit to control the refresh operation based on the refresh control signal.

Also, the refresh control circuit may include a generator to generate the refresh control signal. The refresh control circuit may include a refresh control block to count time in response to the refresh control signal and to output the refresh control signal based on the counted value. The refresh control circuit may include a delay circuit to delay the refresh control signal. The refresh control signal may be a power oscillator signal. The refresh operation may be a self-refresh operation. At least one of the plurality of memory chips may include a vertical electric connection structure.

In accordance with another embodiment, a memory system includes a stacked memory device and a system-on-chip including a memory controller to control the stacked memory device, where the stacked memory device may be in accordance with the aforementioned embodiment.

In accordance with another embodiment, a method for operating a stacked memory device including a plurality of memory chips includes generating a refresh control signal; and performing a refresh operation of at least one of the plurality of memory chips according to the refresh control signal. Each of the plurality of memory chips receives the refresh control signal through a same path.

Also, performing the refresh operation may include delaying the refresh control signal; and performing the refresh operation of at least one of the plurality of memory chips in response to the delayed refresh control signal. Performing the refresh operation may also include counting a time in response to the refresh control signal; and performing the refresh operation of at least one of the plurality of memory chips according to the counted time.

Also, performing the refresh operation may include performing a refresh operation for each of the plurality of memory chips according to the refresh control signal, wherein each of the plurality of memory chips performs a refresh operation at a time different from the refresh operation performed by remaining ones of the plurality of memory chips.

In accordance with another embodiment, a stacked memory device may include a plurality of memory chips; and a controller to control the plurality of memory chips, wherein the controller controls the memory chips to perform refresh operations during non-overlapping time periods. Each memory chip may includes a plurality of rank, each rank may include at least one memory bank, and the controller may control the refresh operation to be selectively performed for a first rank in each of the memory chips during the non-overlapping time periods independently from a refresh operation performed for a second rank in each memory chip.

Also, the first rank in each of the memory chips may be included in a same channel. A connection structure may connect the first rank in each of the memory chips, the connector structure to send a refresh control signal from the controller to a refresh control circuit in each of the memory chips. The refresh control signal is a power oscillation signal.

### BRIEF DESCRIPTION OF THE DRAWINGS

Features will become apparent to those of ordinary skill in the art by describing in detail exemplary embodiments with reference to the attached drawings in which:

FIG. 1 illustrates an embodiment of a stacked memory device;

FIG. 2 illustrates one of a plurality of memory chips in FIG. 1;

FIG. 3 is a diagram explaining an embodiment of a second path in FIG. 1;

FIG. 4 is a diagram explaining another embodiment of the second path;

FIG. 5 illustrates an embodiment of a refresh control circuit in FIG. 2;

FIG. 6 illustrates another embodiment of the refresh control circuit in FIG. 2;

FIG. 7 illustrates another embodiment of the refresh control circuit in FIG. 2;

FIG. 8 illustrates an embodiment of one of the ranks in FIG. 2;

FIG. 9 illustrates an embodiment of timing diagram for operating the stacked memory device in FIG. 1;

FIG. 10 illustrates another embodiment of a timing diagram for operating the stacked memory device in FIG. 1;

FIG. 11 illustrates another embodiment of a timing diagram for operating the stacked memory device in FIG. 1;

FIG. 12 illustrates another embodiment of a timing diagram for operating the stacked memory device in FIG. 1;

FIG. 13 illustrates an embodiment of a method of operating the stacked memory device shown in FIG. 1;

FIG. 14 illustrates another embodiment of a method of operating the stacked memory device in FIG. 1; and

FIG. 15 illustrates an embodiment of a memory system including the stacked memory device in FIG. 1.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

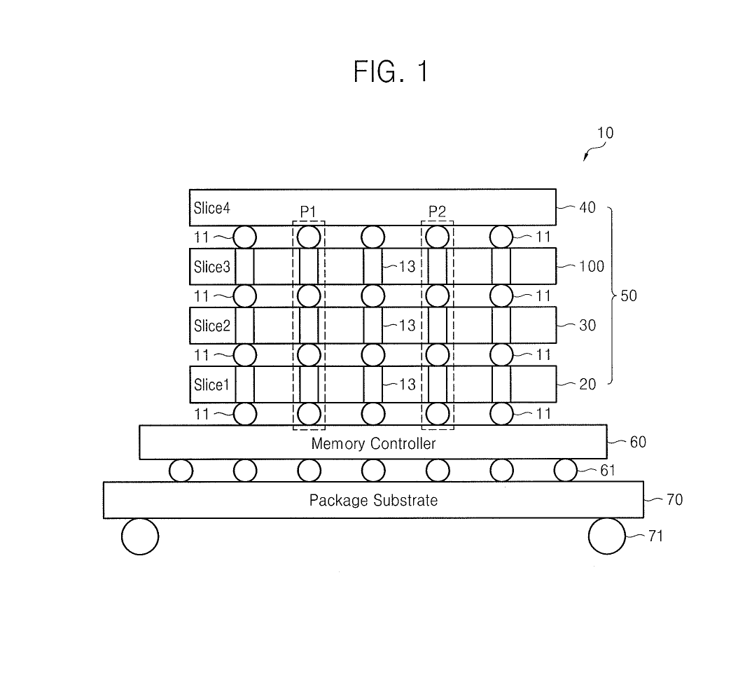

FIG. 1 illustrates a cross-sectional view of an embodiment of a package of a stacked-memory device. Referring to FIG. 1, the stacked memory device 10 may be embodied within a system-in-package (SiP). That is, the stacked memory device 10 may be embodied into one package. The stacked memory device 10 includes a plurality of memory chips 20, 30, 100, and 40, and a memory controller 60. The memory chips 20, 30, 100, and 40 may be non-volatile memories, such as, but not limited to, a dynamic random access memories (DRAMs).

The memory controller 60 is mounted on a package substrate 70, when the stacked memory device 10 is embodied into a SiP. One or more first microbumps 61 are included to attache the memory controller 60 to the package substrate 70. The package substrate 70 may be a printed circuit board (PCB). A plurality of solder balls 71 attaches the package substrate 70 to a system board or an external or host device.

The memory controller 60 controls the plurality of memory chips 20, 30, 100, and 40. The stacked memory device 10 may include an application processor instead of the memory controller 60 in some embodiments. The memory controller 60 may be included in the application processor, when the stacked memory device 10 includes the application processor. Also, in alternative embodiments, the application processor may be embodied into a system on chip (SoC), a multimedia processor, or an integrated circuit.

The plurality of memory chips 20, 30, 100, and 40 are stacked on the memory controller 60. The number of the memory chips 20, 30, 100, and 40 may be vary, for example, based on the intended application. The plurality of memory chips 20, 30, 100, and 40 may be collectively referred to as a stack 50, and each of the memory chips 20, 30, 100, and 40 may be referred to as a slice. Hereinafter, the term “slice” may be used instead of a memory chip, with the understanding that both terms may be synonymous. One or more second microbumps 11 may be used for attaching the plurality of memory chips 20, 30, 100, and 40 with each other.

The memory chips 20, 30, and 100 include vertical electrical connection (e.g., conductive) structures 13 to establish connection with the memory controller 60 electrically. The electrical connection structures may form at least two paths P1 and P2. The first path P1 transmits a command signal (for example, a write enable signal) to at least one of the plurality of memory chips 20, 30, 100, and 40. The second path P2 transmits a refresh control signal for controlling the refresh operation of at least one of the plurality of memory chips 20, 30, 100, and 40. The vertical electrical connection structures 13 may be, for example, through silicon vias (TSVs). In one embodiment, the memory chip 40 may not include the vertical electrical connection structure.

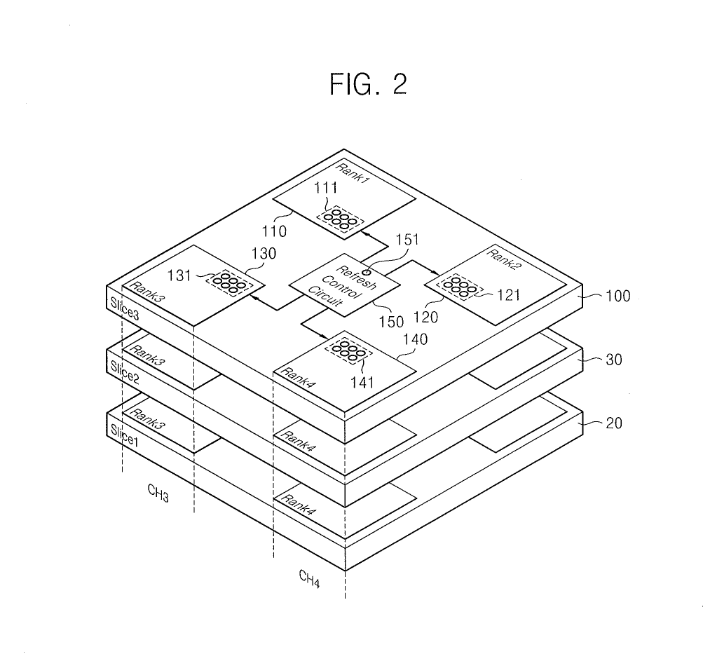

FIG. 2 illustrates an embodiment of one of the plurality of memory chips in FIG. 1. Referring to FIGS. 1 and 2, in this embodiment, each of the plurality of memory chips 20, 30, 100, and 40 includes a plurality of ranks and a refresh control circuit. The refresh control circuit controls a refresh operation for each of the plurality of ranks. The third memory chip 100 among the plurality of memory chips 20, 30, 100, and 40 is explained for convenience of explanation, but the structure of the third memory chip 100 may be applied to another memory chips 20, 30, or 40 in common.

The third memory chip (or third slice 100) includes a plurality of ranks 110, 120, 130, and 140. Each of the plurality of ranks 110, 120, 130, and 140 includes a plurality of pads 111, 121, 131, and 141 corresponding to respective ones of the second microbumps 11.

Each of the plurality of memory chips 20, 30, 100, and 40 performs various operations (for example, refresh operation) independently from one another. Also, each of the plurality of ranks 110, 120, 130, and 140 performs various operations (for example, refresh operation) independently from one another.

The refresh operation of each of the plurality of ranks 110, 120, 130, and 140 is controlled by a refresh control circuit 150. The refresh control circuit 150 includes a pad 151. A refresh control signal, generated by the memory controller 60 or another memory chip 20, 30, or 40, may be received by the refresh control circuit 150 through the pad 151. That is, a refresh control signal is transmitted along the second path P2 shown in FIG. 1, and the third slice 100 receives the refresh control signal through the pad 151. The refresh control signal may be, for example, a power oscillator (POSC) signal.

One or more of the ranks in each of the plurality of memory chips 20, 30, 100, and 40 are electrically connected to each other through the vertical electrical structure 13. For example, Rank 3 in the chips are connected and/or Rank 4 in the chips may be connected. Channels are formed among the plurality of memory chips 20, 30, 100, and 40. For example, channel CH3 may be formed from a connection of Ranks 3 in the chips and channel CH4 may be formed from a connection of Ranks 4 in the chips.

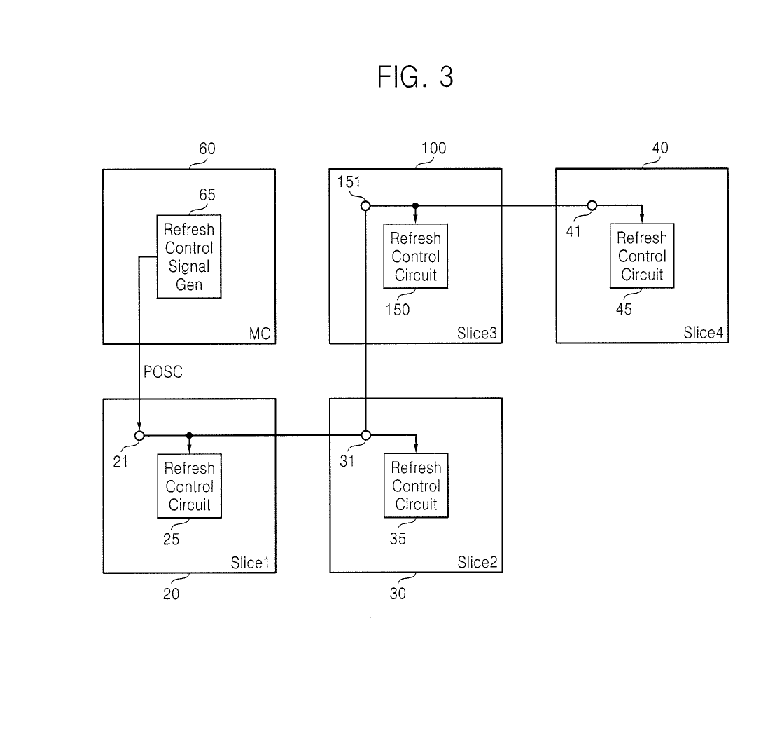

FIG. 3 is a diagram explaining one embodiment of the second path shown in FIG. 1. For convenience of explanation, the path is shown to pass from the memory controller 60 through the memory chips and pads. Also, the refresh control circuit of each chip is shown. In FIG. 3, the pad for the refresh control circuit is shown to be separate from the refresh control circuit. However, in other embodiments, the pad may be included in the refresh control circuit.

Referring to FIGS. 1 through 3, the memory controller 60 includes a refresh control signal generator 65 to generate a refresh control signal, for example, POSC. The refresh control signal POSC is transmitted from the memory controller 60 to the refresh control circuit 25 in the first memory chip 20. The refresh control circuit 25 controls the refresh operation of one rank, for example, Rank 4, in response to the refresh control signal POSC. In some embodiments, the refresh control circuit 25 may generate a refresh control signal POSC, instead of the memory controller 60.

The refresh control signal POSC is transmitted to the refresh control signal 35 of the second memory chip 30 through pads 21 and 31. The refresh control signal 35 controls the refresh operation of one rank in response to the refresh control signal POSC.

The refresh control circuit 150 in memory chip 100 and the fourth refresh control circuit 45 in memory chip 40 receive the refresh control signal POSC through pads 151 or 41 similarly to the refresh control circuit 25. Thus, the refresh control signal may be sent to the rank in each memory chip that corresponds to a same channel.

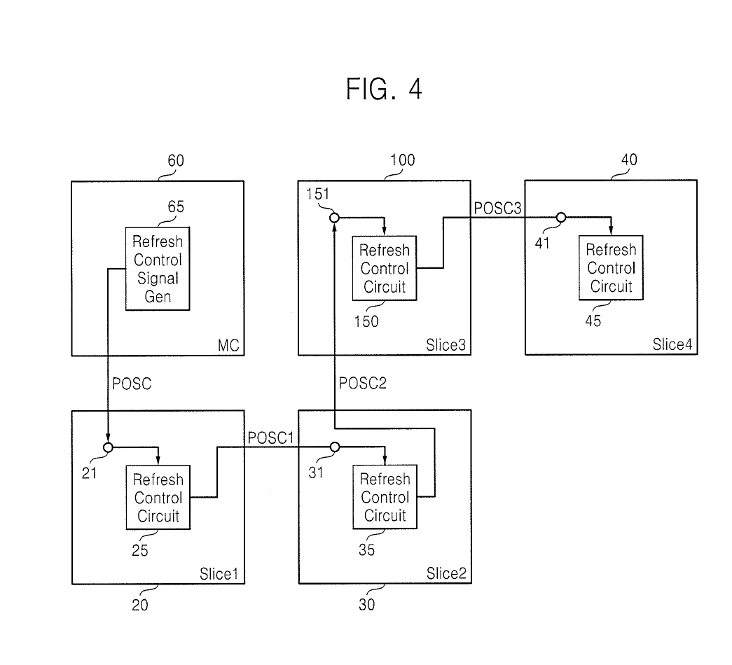

FIG. 4 is a diagram explaining another embodiment of the second path shown in FIG. 1. Referring to FIGS. 1, 2, and 4, the memory controller 60 includes the refresh control signal generator 65. The refresh control signal generator 65 generates a refresh control signal, for example, POSC. In some embodiments, the memory chip 20, 30, 100 or 40 may generate a refresh control signal POSC.

The refresh control signal POSC is transmitted to the first refresh control circuit 25 through the pad 21 of the first slice 20. The first refresh control circuit 25 controls the refresh operation of one rank (for example, Rank 4) included in the first slice 20 in response to the refresh control signal POSC.

A first refresh control signal POSC1 output from the first refresh control circuit 25 is transmitted to the second refresh control circuit 35 through the pad 31. The second refresh control circuit 35 delays the first refresh control signal POSC1 and generates a second refresh control signal POSC2. The second refresh control circuit 35 controls the refresh operation of one rank included in the second slice 30 in response to the second refresh control signal POSC2 and outputs the second refresh control signal POSC2.

The second refresh control signal POSC2 output from the second refresh control circuit 35 is transmitted to the third refresh control circuit 150 through the pad 151. The third refresh control circuit 150 delays the second refresh control signal POSC2 and generates a third refresh control signal POSC3. The third refresh control signal 150 controls the refresh operation of one rank included in the third slice 100 in response to the third refresh control signal POSC3 and outputs the third refresh control signal POSC3.

The third refresh control signal POSC3 output from the third refresh control circuit 150 is transmitted to the fourth refresh control circuit 45 through the pad 41.

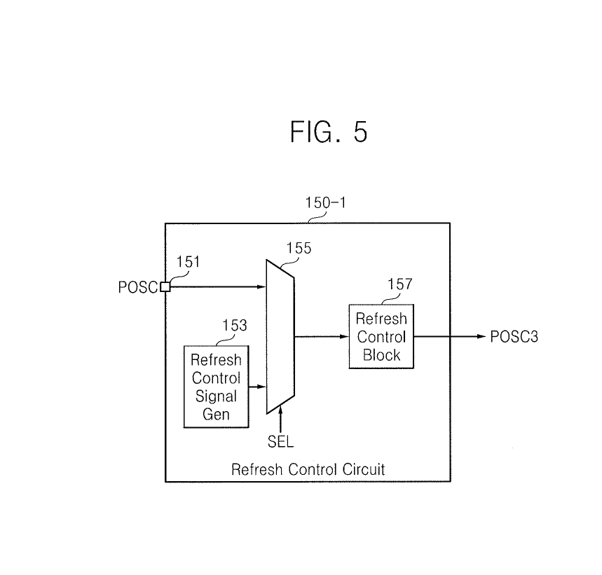

FIG. 5 illustrates an embodiment of a refresh control circuit in FIG. 2. Referring to FIGS. 1, 2, 3, and 5, a refresh control circuit 150-1 includes a refresh control signal generator 153, a selector 155, and a refresh control block 157.

The refresh control signal generator 153 generates a refresh control signal, for example, POSC signal. In some embodiments, the refresh control signal generator 153 may be set so as not to be operated.

The selector 155 outputs one of a first refresh control signal transmitted from the pad 151 or a second refresh control signal output from the refresh control signal generator 153 as a refresh control signal. A selecting signal SEL is set such that the selector 155 selects the first refresh control signal, when the first refresh control signal is generated by the memory controller 60 or another other slice 20, 30, or 40. On the contrary, a selecting signal SEL is set such that the selector 155 selects the second refresh control signal, when the first refresh control signal may not be generated by the memory controller 60 or another slice 20, 30, or 40, that is, when the third slice 100 generates the second refresh control signal. The selector 155 may be embodied into a multiplexer or another type of selector circuit.

The refresh control block 157 counts time in response to the refresh control signal output from the selector 155 and outputs the refresh control signal into one of the plurality of ranks 110, 120, 130, and 140 according to the counting result. The operation of the refresh control block 157 will be described in greater detail below.

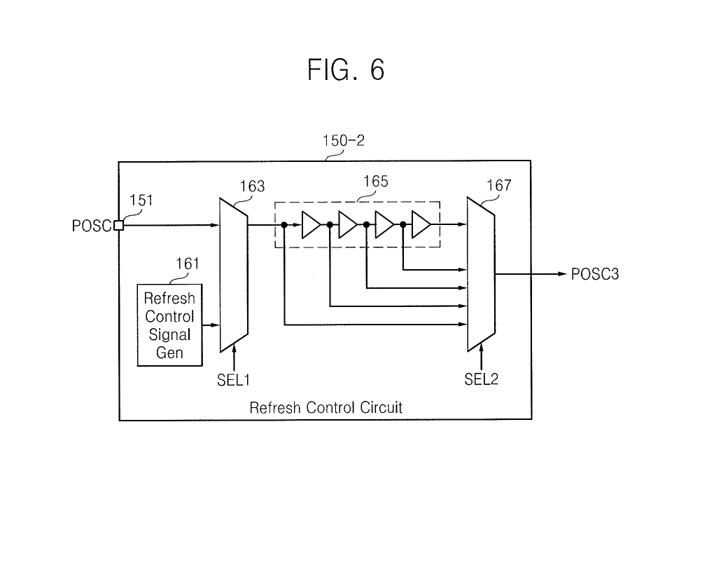

FIG. 6 illustrates another embodiment of the refresh control circuit shown in FIG. 2. Referring to FIGS. 1, 2, 3, and 6, a refresh control circuit 150-2 includes a refresh control signal generator 161, a first selector 163, a delay circuit 165, and a second selector 167.

The refresh control signal generator 161 generates a refresh control signal, for example, POSC. In some embodiments, the refresh control signal generator 161 may be set so as not to be operated.

The first selector 163 outputs one of a first refresh control signal transmitted from the pad 151 and a second refresh control signal output from the refresh control signal generator 161 as a refresh control signal. A first selecting signal SEL1 is set such that the first selector 163 selects the first refresh control signal, when the first refresh control signal is generated by the memory controller 60 or another slice 20, 30, or 40. On the contrary, a first selecting signal SEL1 is set such that the first selector 163 selects the second refresh control signal, when the first refresh control signal may not be generated by the memory controller 60 or another slice 20, 30, or 40.

The delay circuit 165 delays the refresh control signal output from the first selector 163 and outputs the delayed refresh control signal. The delay circuit 165 includes a plurality of buffers connected in series.

The second selector 167 outputs one of the delayed refresh control signals output from the delay circuit 165 to one of the plurality of ranks 110, 120, 130, and 140. The second selecting signal SEL2 may be set to have different delay for each memory chip in advance.

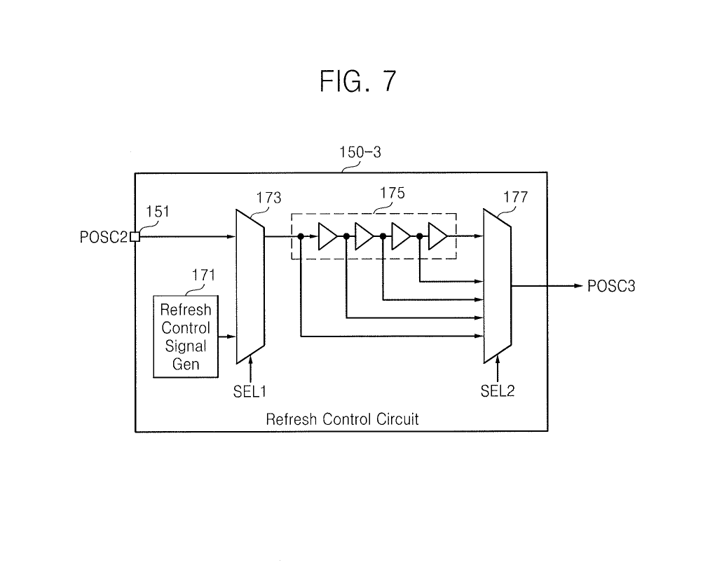

FIG. 7 illustrates another embodiment of the refresh control circuit shown in FIG. 2. Referring to FIGS. 1, 2, 4 and 7, a refresh control circuit 150-3 includes a refresh control signal generator 171, a first selector 173, a delay circuit 175, and a second selector 177.

The refresh control signal generator 171 generates a refresh control signal, for example, POSC signal. In some embodiments, the refresh control signal generator 171 may be set so as not to be operated.

The first selector 173 outputs one of a first refresh control signal POSC2 transmitted through the pad 151 and a second refresh control signal output from the refresh control signal generator 171 as a refresh control signal in response to a first selecting signal SEL1. The first selecting signal SEL1 is set such that the first selector 173 selects the first refresh control signal POSC2, when the first refresh control signal POSC2 is generated by the second slice 30. On the contrary, the first selecting signal SEL1 is set such that the first selector 173 selects the second refresh control signal, when the first refresh control signal POSC2 is not generated by the memory controller 60 or the second slice 30.

The delay circuit 175 delays the refresh control signal output from the first selector 173 and outputs the delayed refresh control signals. The delay circuit 175 includes a plurality of buffers connected in series.

The second selector 177 outputs one of the delayed refresh control signals output from the delay circuit 175 to one of the plurality of ranks 110, 120, 130, and 140 as a refresh control signal POSC3. Also, the second selector 177 outputs the selected refresh control signal POSC3 to the fourth slice 40. A second signal SEL2 is set to have different delay for each memory chip in advance.

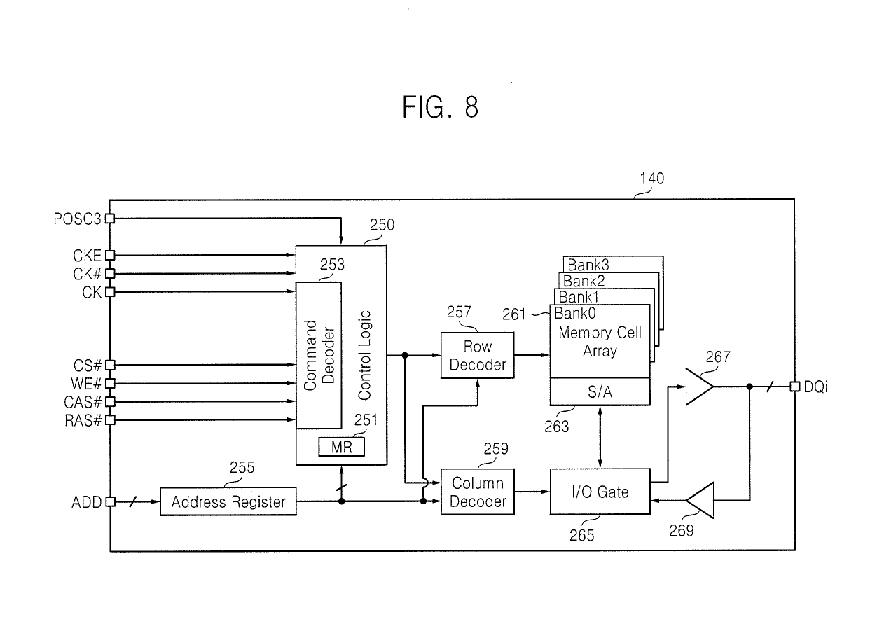

FIG. 8 illustrates an embodiment of one of the plurality of ranks shown in FIG. 2. Referring to FIGS. 1, 2, and 8, the rank 140 includes a control logic 250, an address register 255, a row decoder 257, a column decoder 259, a plurality of memory cell arrays 261, a sense amplifier 263, an input/output gate 265, a driver 267, and a receiver (or an input buffer) 269.

The control logic 250 outputs signals controlling the row decoder 257 and a column decoder 259 in response to a plurality of control signals POSC3, CKE, CK #, CS #, WE #, CAS #, and RAS #.

A clock signal CK, a clock enable signal CKE, and a clock bar signal CK # may be output from a clock driver.

A chip enable bar signal CS #, a write enable bar signal WE #, a column address strobe bar signal CAS #, and a row address strobe bar signal RAS # may be output from the memory controller 60.

The control logic 250 may include one or more mode registers 251 and a command decoder 253. Each mode register 251 stores data for controlling various operation modes of the rank 140.

The command decoder 253 decodes the plurality of control signals CS #, WE #, CAS #, and RAS # and generates control signals for controlling the row decoder 257 and the column decoder 259 according to the decoding result. For example, the command decoder 53 may generate a refresh command when the control signals CS #, RAS #, and CAS # are low and the control signal WE # is high. The refresh command may generate an auto refresh command when the control signal CKE is high and may generate a self refresh command when the control signal CKE is low. The auto refresh operation or the self refresh operation may be performed in response to the refresh control signal POSC.

That is, the command decoder 253 generates control signals for controlling the row decoder 257 and the column decoder 259 according to the endecoded command.

The address register 255 receives an address ADD including a row address and a column address, transmits the row address into the row decoder 257, and transmits the column address into the column decoder 259.

The row decoder 257 decodes a row address received from the address register 255 in response to a control signal output from the control logic 250 and selects one of a plurality of word lines according to the decoding result.

Each of the plurality of memory cell arrays labeled as bank 0 through bank 3 includes a plurality of word lines, a plurality of bit lines, and a plurality of memory cells for storing data.

The sense amplifier 263 senses and amplifiers voltage changes of the plurality of bit lines.

The column decoder 259 decodes a column address output from the address register 255 and generates a plurality of column selecting signals according to the decoding result.

The input/output gate 265 transmits data or signals to the sense amplifier 263, the driver 267, or the receiver 269 output from the column decoder 259.

The input/output gate 265 transmits data DQi received from the receiver 269 to the plurality of memory cell arrays 261 through the driver according to the plurality of column selecting signals output from the column decoder 259 during the write operation. Also, the input/output gate 265 transmits a plurality of signals sense amplified by the sense amplifier 263 to the driver 267 as a data DQi according to the plurality of column selecting signals output from the column decoder 259 during the read operation. The driver 267 outputs the data DQi to the memory controller 60.

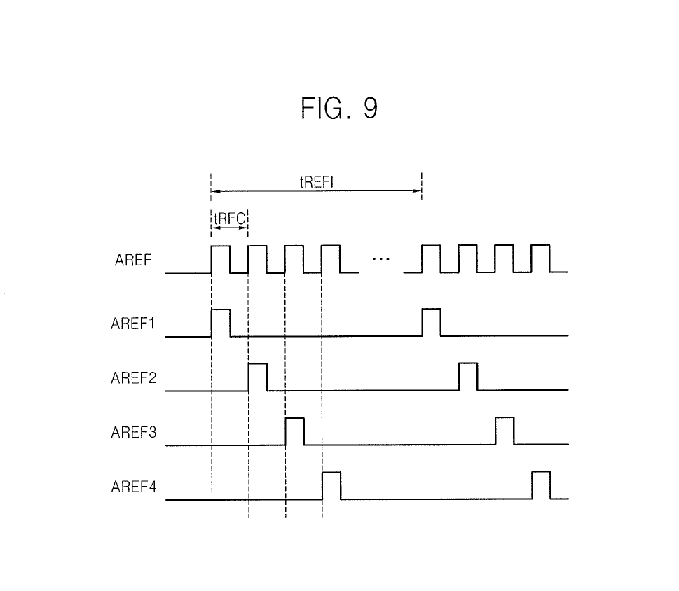

FIG. 9 illustrates an embodiment of a timing diagram for explaining the operation of the stacked memory device in FIG. 1. Referring to FIGS. 1, 2, and 9, the memory controller 60 issues auto refresh commands AREF for performing the auto refresh operation with respect to one rank (e.g., Rank 4) in each of the plurality of memory chips 20, 30, 100, and 40.

Peak current may be generated when the one rank (e.g., Rank 4) in each of the plurality of memory chips 20, 30, 100, and 40 performs the auto refresh operation at the same time. This may affect reliability of the memory chips 20, 30, 100, and 40.

In accordance with one embodiment, the memory controller 60 issues auto refresh commands AREF to the one rank in each chip to ensure that the auto refresh operation is not performed by the one rank in each chip at the same time, to thereby reduce the peak current. The auto refresh commands AREF includes a first through a fourth auto refresh commands AREF1˜4.

The first auto refresh command AREF1 is a command for performing the auto refresh operation for one rank (e.g., Rank 4) in the first memory chip 20. The second auto refresh command AREF2 is a command for performing the auto refresh operation for one rank (e.g., Rank 4) in the second memory chip 30. The third auto refresh command AREF3 is a command for performing the auto refresh operation for one rank (e.g., Rank 4) in the third memory chip 100. The fourth auto refresh command AREF4 is a command for performing the auto refresh operation for one rank (e.g., Rank 4) in the fourth memory chip 40.

Also, in FIG. 9, ‘tREFI’ is the average periodic refresh interval and ‘tRFC’ is the refresh command period time. As shown, the auto refresh command period time of auto refresh commands AFER1, AREF2, AREF3, and AREF4 do not overlap. Accordingly, peak current may not be generated.

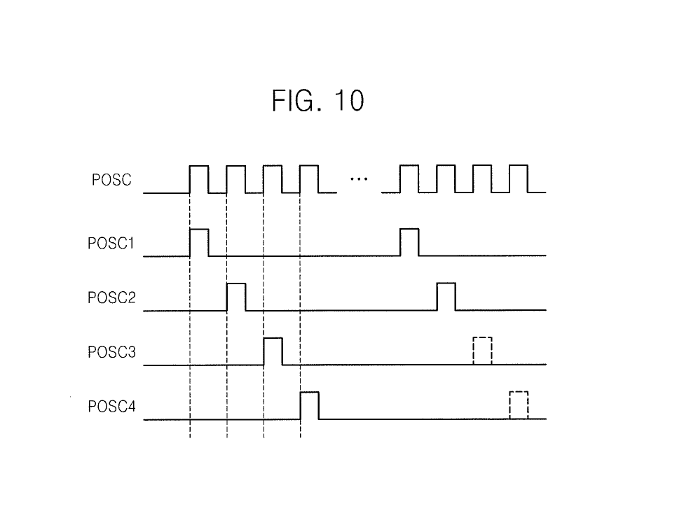

FIG. 10 illustrates another embodiment of a timing diagram for explaining the operation of the stacked memory device in FIG. 1. Referring to FIGS. 1 through 3, 5, and 10, the memory controller 60 issues self-refresh commands for performing a self-refresh operation for one rank (e.g., Rank 4) in each of the plurality of memory chips 20, 30, 100, and 40. Also, the memory controller 60 generates a refresh control signal, for example, POSC.

The first memory chip 20 receives the refresh control signal POSC output from the memory controller 60 through the second path P2. Specifically, the refresh control circuit 25 of the first memory chip 20 counts time in response to the refresh control signal POSC and transmits a first refresh control signal POSC1 for one rank (e.g., Rank 4) of the first memory chip 20 according to the counting result. For example, the refresh control circuit 25 of the first memory chip 20 transmits the first refresh control signal POSC1 to one rank of the first memory chip 20 when the counted value is 1. The self-refresh operation is performed in the one rank (e.g., Rank 4) of the first memory chip 20 in response to the first refresh control signal POSC1.

The second memory chip 30 receives the refresh control signal POSC output from the memory controller 60 through the second path P2. Specifically, the refresh control circuit 35 of the second memory chip 30 counts time in response to the refresh control signal POSC and transmits the second refresh control signal POSC2 to one rank (e.g., Rank 4) of the second memory chip 30. For example, the refresh control block of the second memory chip 30 transmits the second refresh control signal POSC2 to a rank of the second memory chip 30 when the counted value is 2. The self-refresh operation is performed in one rank of the second memory chip 30 in response to the second refresh control signal POSC2.

The third memory chip 100 receives the refresh control signal POSC output from the memory controller 60 through the second path P2. Specifically, the refresh control block 157 of the third memory chip 100 counts time in response to the refresh control signal POSC and transmits the third refresh control signal POSC3 to one rank (e.g., Rank 4) of the third memory chip 100. The refresh control block 157 of the third memory chip 100 transmits the third refresh control signal POSC3 to one rank of the third memory chip 100 when the counted value is 3. The self-refresh operation is performed in the one rank of the third memory chip 100 in response to the third refresh control signal POSC3. The memory controller 60 generates the refresh control signal POSC. Thus, the selector 155 outputs the refresh control signal output from the pad 151 in response to a selecting signal SEL.

The fourth memory chip 40 receives the refresh control signal output from the memory controller through the second path P2. Specifically, a refresh control block of the fourth memory chip 40 counts time in response to the refresh control signal POSC and transmits a fourth refresh control signal POSC4 to one rank (e.g., Rank 4) of the fourth memory chip 40. For example, the refresh control block of the fourth memory chip 40 transmits the fourth refresh control signal POSC4 into the one rank of the fourth memory chip 40 when the counted value is 4. The self-refresh operation is performed in the one rank of the fourth memory chip 40 in response to the fourth refresh control signal POSC4.

Accordingly, the self refresh operation may not be performed with respect to one rank in each of the plurality of memory chips 20, 30, 100, and 40 at the same time by using the refresh control signal POSC. That is, peak current may be reduced.

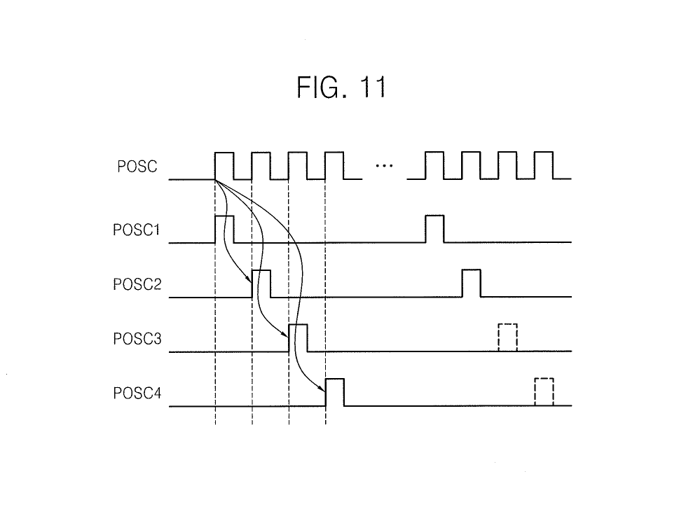

FIG. 11 illustrates another embodiment of a timing diagram for explaining the operation of the stacked memory device in FIG. 1. Referring to FIGS. 1 through 3, 6, and 11, the memory controller 60 issues self-refresh commands for performing the self-refresh operation with respect to one rank in each of the plurality of memory chips 20, 30, 100, and 40. Also, the memory controller 60 generates a refresh control signal, for example, POSC.

The first memory chip 20 receives the refresh control signal output from the memory controller 60 through the second path P2. The refresh control circuit 25 of the first memory chip 20 delays the refresh control signal POSC and outputs a first refresh control signal POSC1. The refresh control circuit 25 of the first memory chip 20 transmits the first refresh control signal POSC1 into one rank of the first memory chip 20. The self-refresh operation is performed in the one rank of the first memory chip 20 in response to the first refresh control signal POSC1.

The second memory chip 30 receives the refresh control signal POSC1 output from the memory controller 60 through the second path P2. The refresh control circuit 35 of the second memory chip 30 delays the refresh control signal POSC and outputs a second refresh control signal POSC2. The refresh control circuit 35 of the second memory chip 30 transmits the second refresh control signal POSC2 into one rank of the second memory chip 30. The self-refresh operation is performed in the one rank of the second memory chip 30 in response to the second refresh control signal POSC2.

The third memory chip 100 receives the refresh control signal POSC output from the memory controller 60 through the second path P2. The refresh control circuit 150-2 of the third memory chip 100 delays the refresh control signal POSC and outputs a third refresh control signal POSC3. That is, the second selector 167 selects one of the plurality of delayed refresh control signals output from the delay circuit 165 and outputs the same as a third refresh control signal POSC3. The refresh control circuit 150-2 of the third memory chip 100 transmits the third refresh control signal POSC3 into one rank of the third memory chip 100. The self-refresh operation is performed in the one rank of the third memory chip 100 in response to the third refresh control signal POSC3. The memory controller 60 generates the refresh control signal POSC. Thus, the first selector 163 outputs the refresh control signal POSC output from the pad 151 in response to a first selecting signal SEL1.

The fourth memory chip 40 receives the refresh control signal output from the memory controller 60 through the second path P2. The refresh control circuit 45 of the fourth memory chip 40 delays the refresh control signal POSC and outputs a fourth refresh control signal POSC4. The refresh control circuit 45 of the fourth memory chip 40 transmits the fourth refresh control signal POSC4 into one rank of the fourth memory chip 40. The self-refresh operation is performed in the one rank of the fourth memory chip 40 in response to the fourth refresh control signal POSC4.

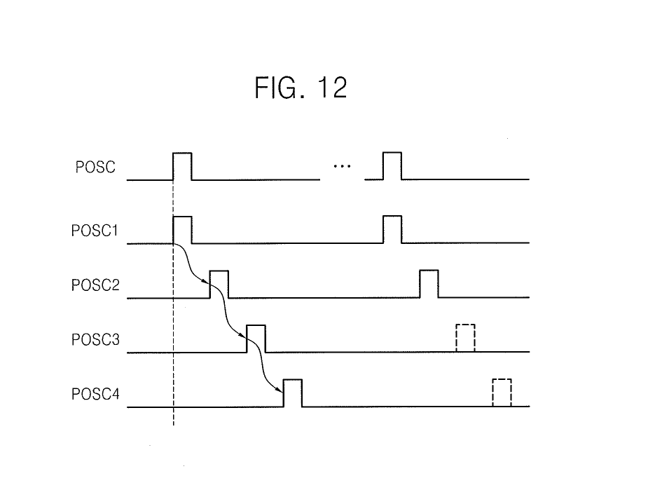

FIG. 12 illustrates another embodiment of a timing diagram for explaining the operation of the stacked memory device in FIG. 1. Referring to FIGS. 1, 2, 4, 7, and 12, the memory controller 60 issues self-refresh commands for performing the self-refresh operation with respect to one rank in each of the plurality of memory chips 20, 30, 100, and 40. Also, the memory controller 60 generates a refresh control signal, for example, POSC.

The first memory chip 20 receives the refresh control signal POSC output from the memory controller 60 through the second path P2. The refresh control circuit 25 of the first memory chip 20 outputs a first refresh control signal POSC1. The first refresh control signal POSC1 and the refresh control signal POSC have the same phase.

The refresh control circuit 25 of the first memory chip 20 transmits the first refresh control signal POSC1 to one rank of the first memory chip 20. The self refresh operation is performed in the one rank of the first memory chip 20 in response to the first refresh control signal POSC1.

The second memory chip 30 receives the first refresh control signal output from the first memory chip 20 through the second path P2. The refresh control circuit 35 of the second memory chip 30 delays the refresh control signal POSC1 and outputs a second refresh control signal POSC2. The refresh control circuit 35 of the second memory chip 30 transmits the second refresh control signal POSC2 into one rank of the second memory chip 30. The self-refresh operation is performed in the one rank of the second memory chip 30 in response to the second refresh control signal POSC2.

The third memory chip 100 receives the second refresh control signal POSC2 output from the second memory chip 30 through the second path P2. The refresh control circuit 150-3 of the third memory chip 100 delays the second refresh control signal POSC2 and outputs a third refresh control signal POSC3. That is, the second selector 177 outputs the third refresh control signal POSC3 by selecting one of the plurality of delayed refresh control signals output from the delay circuit 175. The refresh control circuit 153-3 of the third memory chip 100 transmits the third refresh control signal POSC3 to one rank of the third memory chip 100. The self refresh operation is performed in the one rank of the third memory chip 100 in response to the third refresh control signal POSC3.

The fourth memory chip 40 receives the third refresh control signal POSC3 output from the third memory chip 100 through the second path P2. Specifically, the refresh control circuit 45 of the fourth memory chip 40 delays the third refresh control signal POSC3 and output a fourth refresh control signal POSC4. The refresh control circuit 45 of the fourth memory chip 40 transmits the fourth refresh control signal POSC4 to one rank of the fourth memory chip 40. The self-refresh operation is performed in the one rank of the fourth memory chip 40 in response to the fourth refresh control signal POSC4.

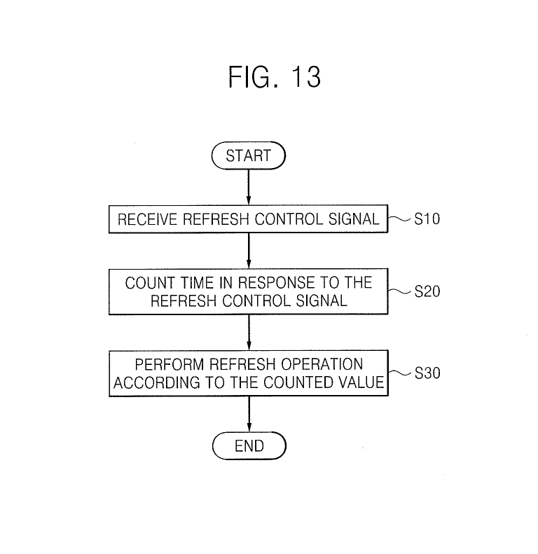

FIG. 13 illustrates an embodiment of a method for operating the stacked memory device shown in FIG. 1. Referring to FIGS. 1 through 3, 5, 10, and 13, the refresh control circuit 150 of the third slice 100 receives a refresh control signal, in operation S10.

The refresh control block 157 counts time in response to the refresh control signal, in operation S20. The refresh control block 157 transmits a third refresh control signal POSC3 to one rank (e.g., Rank 4) of the third slice 100 according to the counting result. The self refresh operation is performed in one rank of the third slice 100 in response to the third refresh control signal POSC3, in operation S30, when the counted value is 3.

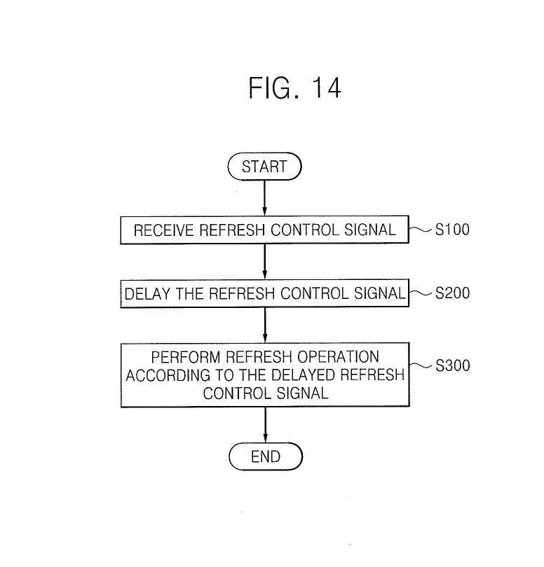

FIG. 14 illustrates another embodiment of a method for operating the stacked memory device in FIG. 1. Referring to FIGS. 1 through 3, 6, 11, and 14, the refresh control circuit 150 of the third slice 100 receives a refresh control signal POSC, in operation S100. The refresh control signal POSC is received from the memory controller 60.

The delay circuit 165 delays the refresh control signal POSC and outputs a plurality of delayed refresh control signals. The second selector 167 outputs one of the plurality of delayed refresh control signals as a third refresh control signal POSC3, in operation S200.

Any one of the plurality of ranks (e.g., Rank 4 in the third slice 100 performs the self-refresh operation in response to the third refresh control signal POSC3, in operation S300. The refresh control signal 150 of the third slice 100 receives a second refresh control signal POSC2 in some embodiments. The second refresh control signal POSC2 is received from the second slice 30.

Referring to FIG. 7, the delay circuit 175 delays the second refresh control signal POSC2 and outputs a plurality of delayed refresh control signals. The second selector 177 outputs one of the plurality of delayed refresh control signals as a third refresh control signal POSC3 in response to a second select signal SEL2.

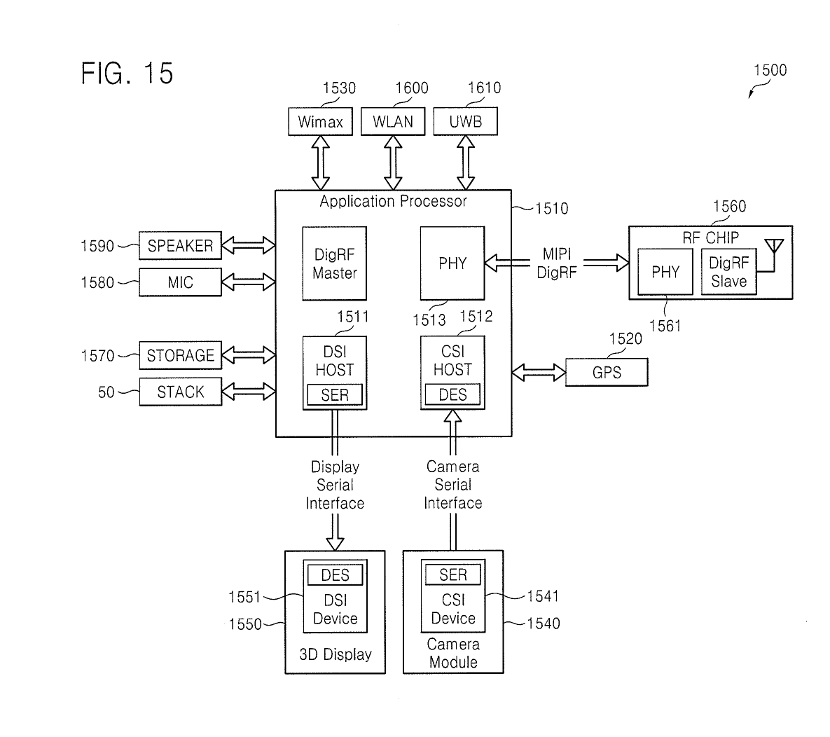

FIG. 15 illustrates an embodiment of a memory system including the stacked memory device in FIG. 1. Referring to FIGS. 1 and 15, the memory system 1500 may be embodied into a portable device using or supporting an MIPI interface, personal digital assistant (PDA), portable multi-media player (PMP), tablet PC, or smart phone.

The memory system 1500 includes an application processor 1510, a stack 50, a camera module 1540, and a 3D display 1550.

The stack includes the plurality of memory chips 20, 30, 100, and 40 in FIG. 1.

The application processor 1510 includes the memory controller 60 in FIG. 1.

A CSI host 1512 embodied in the application processor 1510 performs serial communication with a CSI device 1541 of the camera module 1540 through a camera serial interface (CSI). At this time, for example, the CSI host 1512 includes a deserializer DES, and the CSI device 1541 includes a serializer SER.

A DSI host 1511 embodied in the application processor 1510 performs serial communication with a DSI device 1551 of the 3D display 1550 through a display serial interface (DSI). At this time, for example, the DSI host 1511 includes a serializer SER, and the DSI device 1551 includes a deserializer DES.

The memory system 1500 further includes an RF chip 1560 communicating with the application processor 1510. A PHY 1513 of the memory system 1500 and a PHY 1561 of the RF chip 1560 exchange data according to MIPI DigRF.

The memory system 1500 further includes a GPS receiver 1520, a storage 1570, a mike 1580, and a speaker 1590, and the memory system 1500 communicates by using a Wimax 1530, a WLAN 1500, and a UWB 1610.

In the aforementioned embodiments, the same number rank of each memory chip is described as corresponding to a same channel. However, in other embodiments, different number ranks may correspond to a channel. Also, in the aforementioned embodiments, only one rank in each chip is subject to a refresh operation. However, in other embodiments, more than one rank in each chip may be refreshed at the same or different times, for example, in response to a POSC or other refresh control signal transmitted along path P2 or another path. Also, a refresh operation may be performed for multiple ranks in one chip independently and at different times from refresh operations performed for rank(s) in other chips.

The stacked memory device, the system including the same, and the method for operating the system according to one or more of the aforementioned embodiments have an effect of reducing peak current during the refresh operation in the stacked memory device by preventing the refresh operation from being performed in ranks included in the memory system at the same time.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A stacked memory device, comprising:
a plurality of memory chips;
a first path to transmit a command signal to at least one of the plurality of memory chips; and
a second path coupled to the plurality of memory chips, the second path to transmit a refresh control signal for controlling a refresh operation of at least one of the plurality of memory chips.

2. The stacked memory device as claimed in claim 1, further comprising:
a memory controller to control the plurality of memory chips, and
wherein the memory controller includes a generator to generate the refresh control signal.

3. The stacked memory device as claimed in claim 1, wherein at least one of the plurality of memory chips includes a refresh control circuit to control the refresh operation based on the refresh control signal.

4. The stacked memory device as claimed in claim 3, wherein the refresh control circuit includes a generator to generate the refresh control signal.

5. The stacked memory device as claimed in claim 3, wherein the refresh control circuit includes a refresh control block to count time in response to the refresh control signal and to output the refresh control signal based on the counted value.

6. The stacked memory device as claimed in claim 3, wherein the refresh control circuit includes a delay circuit to delay the refresh control signal.

7. The stacked memory device as claimed in claim 1, wherein the refresh control signal is a power oscillator signal.

8. The stacked memory device as claimed in claim 1, wherein the refresh operation is a self-refresh operation.

9. The stacked memory device as claimed in claim 1, wherein at least one of the plurality of memory chips includes a vertical electrical connection structure.

10. A memory system comprising:
the stacked memory device as claimed in claim 1; and
a system-on-chip including a memory controller to control the stacked memory device.

11. A method for operating a stacked memory device including a plurality of memory chips, the method comprising:
generating a refresh control signal; and
performing a refresh operation of at least one of the plurality of memory chips according to the refresh control signal.

12. The method as claimed in claim 11, wherein each of the plurality of memory chips receives the refresh control signal through a same path.

13. The method as claimed in claim 11, wherein performing the refresh operation comprises:
delaying the refresh control signal; and
performing the refresh operation of at least one of the plurality of memory chips in response to the delayed refresh control signal.

14. The method as claimed in claim 11, wherein performing the refresh operation comprises:
counting a time in response to the refresh control signal; and
performing the refresh operation of at least one of the plurality of memory chips according to the counted time.

15. The method as claimed in claim 11, wherein performing the refresh operation includes:
performing a refresh operation for each of the plurality of memory chips according to the refresh control signal, wherein each of the plurality of memory chips performs a refresh operation at a time different from the refresh operation performed by remaining ones of the plurality of memory chips.

16. A stacked memory device, comprising:
a plurality of memory chips; and
a controller to control the plurality of memory chips,
wherein the controller controls the memory chips to independently perform refresh operations during non-overlapping time periods.

17. The stacked memory device of claim 16, wherein:
each memory chip includes a plurality of ranks,
each rank includes at least one memory bank, and
the controller controls the refresh operation to be selectively performed for a first rank in each of the memory chips during the non-overlapping time periods independently from a refresh operation performed for a second rank in each memory chip.

18. The stacked memory device of claim 17, wherein the first rank in each of the memory chips is included in a same channel.

19. The stacked memory device of claim 18, further comprising:
a connection structure to connect the first rank in each of the memory chips, the connection structure to send a refresh control signal from the controller to a refresh control circuit in each of the memory chips.

20. The stacked memory device of claim 19, wherein the refresh control signal is a power oscillation signal.
